(19) United States
(12) Patent Application Publication
(10) Pub. No.: US 2026/0058408 A1
(43) Pub. Date: Feb. 26, 2026

(54) QUICK DISCONNECT ELECTRICAL CONNECTION STRUCTURE FOR FAN MODULE

(71) Applicant: ASIA VITAL COMPONENTS (CHINA) CO., LTD., SHENZHEN CITY (CN)

(72) Inventors: SUNG-WEI SUN, SHENZHEN CITY (CN); FENG LIU, SHENZHEN CITY (CN); JING-PING HUANG, SHENZHEN CITY (CN)

(21) Appl. No.: 18/814,090

(22) Filed: Aug. 23, 2024

(30) Foreign Application Priority Data
May 31, 2024 (TW) 113120389

(51) Int. Cl. H01R 13/633; G06F 1/20; H01R 12/72; H01R 12/78; H01R 12/79; H01R 13/03; H01R 25/00

(52) U.S. Cl. CPC H01R 13/633; H01R 12/721; H01R 12/78; H01R 12/79; H01R 13/03; H01R 25/006; G06F 1/20

(57) ABSTRACT

A quick disconnect electrical connection structure for fan module includes fan units assembled to a fan frame and respectively including an electrical connection section located facing toward an electrical connection side of the fan frame, and a fan electrical adapter board connected to the electrical connection side of the fan frame and having mating electrical connection sections provided thereon corresponding to the electrical connection sections. The mating electrical connection sections and other circuit arrangements on the fan electrical adapter board together form an external connection terminal for electrically connected to an external device. Flexible electrical cords with one or more quick disconnect electrical connectors provided thereon are used to adapt to any misalignment between the electrical connection sections and the mating electrical connection sections while quickly connect them to one another, enabling improved sharing ratio of the fan units and the fan electrical adapter board used in different working environments.

### FIELD OF THE INVENTION

The present invention relates to a quick disconnect electrical connection structure for fan module, and more particularly, to an improved electrical connection structure between fan units and a fan electrical adapter board.

### BACKGROUND OF THE INVENTION

The electronic technology progresses day by day and the demand for more powerful computer function also increases constantly. The small-scale computer or server device with one single processor in the early stage has been developed nowadays into sharing server equipment that includes multiple sets of server devices at the same time. Compared to the small-scale server devices, the sharing server equipment processes data in a much more massive scale, which requires for higher and higher power consumption and produces extremely huge amount of heat during the computing operation. To enable sufficient dissipation of the huge amount of heat produced during working, the sharing server equipment would usually adopt a fan wall that consists of a plurality of fan modules, which respectively include a plurality parallelly arranged fans. And, fans of different sizes or specifications are used to adapt to differently sized or scaled server equipment, so as to achieve optimal heat dissipation efficiency of different fan modules. In the conventional fan module, there are included a plurality of fan units. All the fan units have a common power source supplied from at least one motherboard in the server equipment. FIG. 1 shows an early stage electrical connection structure, in which a plurality of fan units 11 is mounted on a fan module rack 10. The fan units 11 respectively have an individual electrical connection cord 110. The individual electrical cords 110 respectively extend from the fan units 11 to connect directly to a corresponding electrical connector 120 on the motherboard 12. Since the distances between the electrical connectors 120 on the motherboard 12 and the individual fan units 11 are not the same, the electrical connection cords 110 connected to the electrical connectors 120 not only occupy a lot of space in the serve cabinet to adversely influence the application efficiency of the fan module rack space, but also tend to tangle with one another disorderly in the fan module rack 10 and must be organized in the electrical connection process.

To overcome the problem in the conventional fan module shown in FIG. 1, one side of the fan module rack 10 corresponding to the electrical connection cords 110 of the fan units 11 is defined as a cord outlet side 101, which is closed by a cord covering plate 102 as shown in FIG. 2. The electrical connection cords 110 are gathered and extended along the cord outlet side 101 to connect to the electrical connectors 120 on the motherboard 12 from the same end of the fan module rack 10, as shown in FIG. 1. In this case, the electrical connection cords 110 of the fan units 11 are preliminarily organized but they are still extended between the fan units 11 and the motherboard 12 to occupy a lot of usable space in the fan module rack 10. When the fan module is to be disconnected from the motherboard 12 for the purpose of replacement or maintenance, a plurality of complicate procedures is involved to cause inconvenience in working.

To overcome the above problems in the conventional fan module electrical connection, an improved electrical connection structure for fan module as shown in FIG. 3 is developed. In this case, the improvement includes a fan adapter circuit board 103, which is assembled to the fan module rack 10. The fan units 11 are respectively provided with an electrical connector 112, and the adapter circuit board 103 is provided with circuits corresponding to the fan units 11 and mating electrical connectors 104 corresponding to the electrical connectors 112. Therefore, the electrical connectors 112 and the corresponding mating electrical connectors 104 can be quickly electrically connected; and the adapter circuit board 103 can be electrically connected at one of two ends thereof to the motherboard 12. With these arrangements, the electrical connection between the fan units 11 and the motherboard 12 has been basically improved to eliminate the problems of disordered and space-occupying electrical connection cords 110. However, to ensure all the fan units 11 can be electrically connected at the same time, the quick disconnect electrical connectors 112 and the mating electrical connectors 104 provided on the fan units 11 and the adapter circuit board 103, respectively, must be precisely located to enable accurately electrical connection of the electrical connectors 112 with the mating electrical connectors 104. And, since the fan units 11 in one fan module are the same in model and size, the fan adapter circuit board 103 is designed for use only with the fan units 11 of the specific model or size. In the case fan units 11 of another model or size are used, a new adapter circuit board 103 adaptable for the new fan units 11 must be designed to therefore results in increased production cost. Meanwhile, the fan units 11 and the adapter circuit board 103 applicable for only specific fan model or size are subjected to a largely limited sharing ratio. To overcome this problem, the inventor of the above conventional fan module electrical connection structure further develops an adapter circuit board 103 that is usable with electrical connectors 112 and mating electrical connectors 104 of two different specifications to give the adapter circuit board 103 a wider applicability. However, the above modification to the adapter circuit board 103 by mounting electrical connectors 112 and mating electrical connectors 104 of two different specifications not only increases the complexity in the circuit arrangements on the adapter circuit board 103, but also largely increases the manufacturing cost of the adapter circuit board 103. It is therefore desirable to further improve the conventional fan module electrical connection structure.

### SUMMARY OF THE INVENTION

A primary object of the present invention is to provide a quick disconnect electrical connection structure for fan module, which mainly includes a fan frame, a fan electrical adapter board, and a plurality of fan units. The fan units are assembled to an interior of the fan frame, and respectively include an electrical connection section located at a position facing toward an electrical connection side of the fan frame. The fan electrical adapter board is mounted to the electrical connection side of the fan frame and has mating electrical connection sections provided thereon corresponding to the electrical connection sections of the fan units. The mating electrical connection sections and other circuit arrangements provided on the fan electrical adapter board together form an external connection terminal for electrically connected to an external device. The present invention is characterized in that at least a part of the electrical connection structures for quickly connecting the electrical connection sections to the mating electrical connection sections are configured as flexible electrical cords with one of more quick disconnect electrical connectors provided therewith. With the flexible electrical cords, any difference in the specification or size between the fan units or the fan electrical adapter board or any disalignment between the electrical connection sections and the mating electrical connection sections can be flexibly overcome, allowing the fan module to be used in different working environments or using conditions, and enabling the fan units and the fan electrical adapter board to have improved sharing ratio.

In the above electrical connection structure for fan module, the external connection terminal can be an electrical terminal in the form of a flat piece with a plurality of gold fingers terminals or a quick disconnect electrical connection terminal. And, the fan module can be electrically connected to a motherboard via the gold fingers electrical connection terminals or a flat cable having the quick disconnect electrical connection terminals without the need of connecting the fan units to the motherboard via individual electrical connection cords, so that complicate and disordered wiring is avoided to save the space in the server cabinets or racks.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view showing a conventional electrical connection structure for fan module, in which each fan unit is connected directly to a motherboard via an individual electrical connection cord;

FIG. 2 shows all the electrical connection cords in the conventional fan module electrical connection structure of FIG. 1 are gathered at one side of a fan module support and covered by a cord covering plate;

FIG. 3 shows another conventional fan module electrical connection structure that uses a fan adapter circuit board to enable quick electrical connection between each fan units and a motherboard;

FIG. 4 is a partially exploded perspective view of a quick disconnect electrical connection structure for fan module according to a first operable embodiment of the present invention;

FIG. 4A is an enlarged view of the circled area of FIG. 4;

FIG. 5 is a partially exploded perspective view of a quick disconnect electrical connection structure for fan module according to a second operable embodiment of the present invention;

FIG. 5A is an enlarged view of the circled area of FIG. 5;

FIG. 6 is a partially exploded perspective view of a quick disconnect electrical connection structure for fan module according to a third operable embodiment of the present invention;

FIG. 6A is an enlarged view of the circled area of FIG. 6; and

FIG. 7 is a fragmentary, perspective view showing an external connection terminal according to an operable embodiment of the present invention.

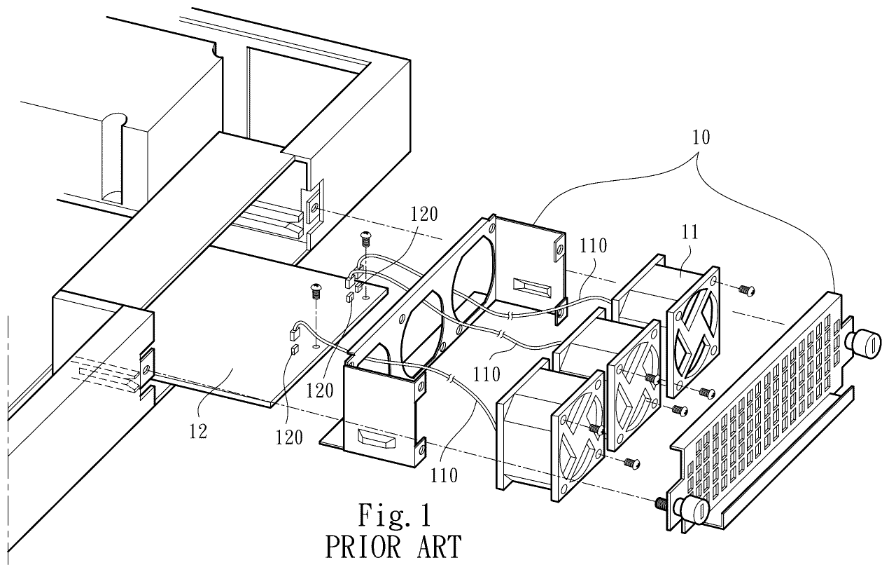

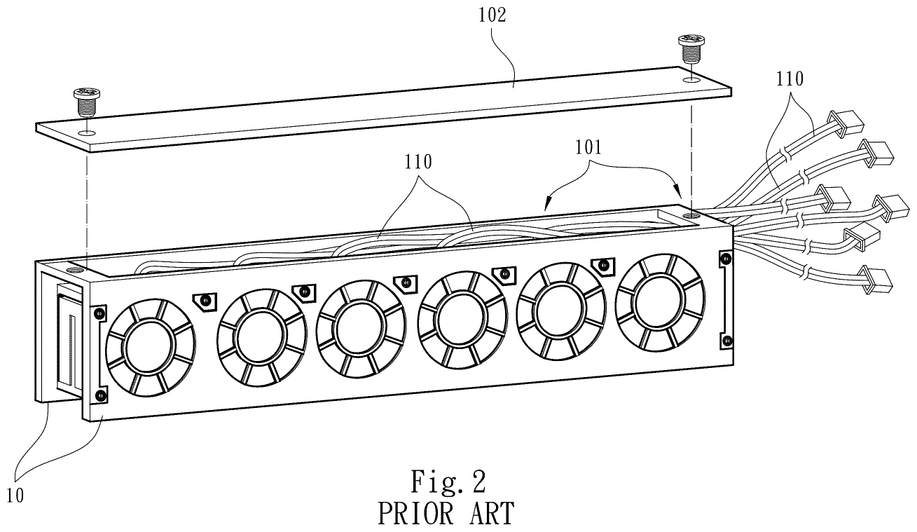

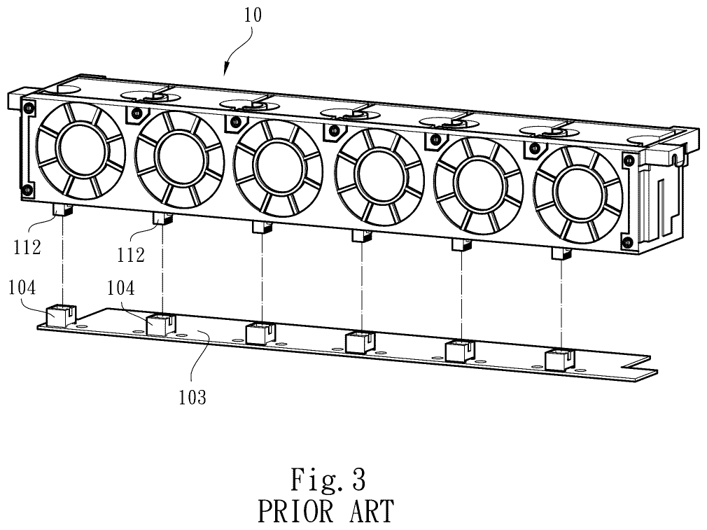

### DETAILED DESCRIPTION OF THE PREFERRED EMBODIMENTS

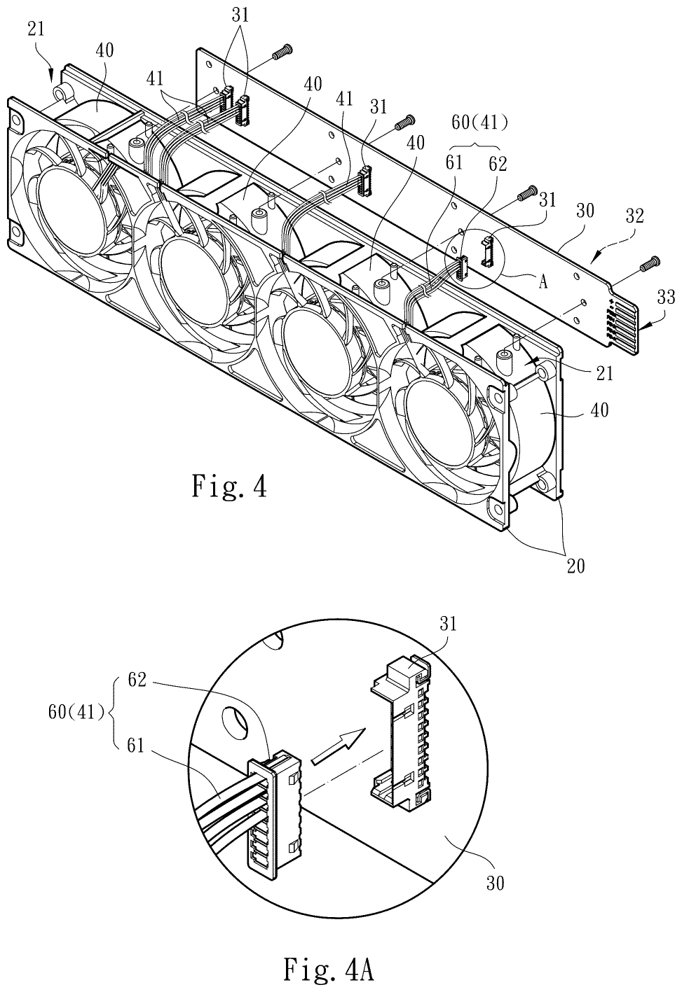

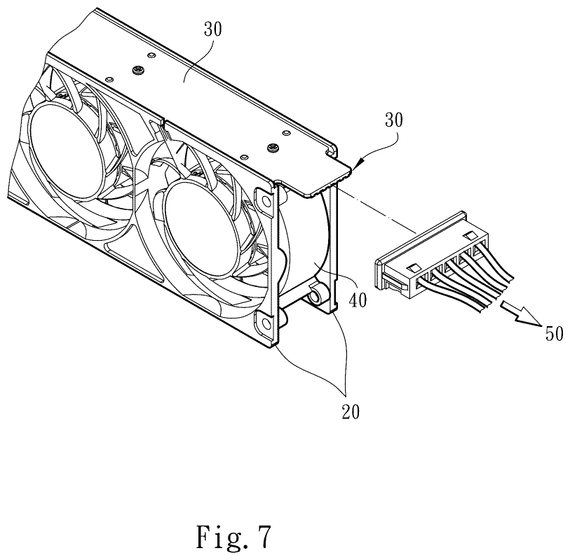

Please refer to FIGS. 4 to 7. A quick disconnect electrical connection structure for fan module according to the present invention mainly includes a fan frame 20, a fan electrical adapter board 30, and a plurality of fan units 40. The fan units 40 are assembled to an interior of the fan frame 20 and respectively include an electrical connection section 41 located at a position facing toward an electrical connection side 21 of the fan frame 20. The fan electrical adapter board 30 is connected to the electrical connection side 21 and has mating electrical connection sections 31 provided thereon corresponding to the electrical connection sections 41 of the fan units 40. The mating electrical connection sections 31 and other circuit arrangements 32 provided on the fan electrical adapter board 30 together provide an external connection terminal 33 for electrical connection to an external device. The external connection terminal 33 may be differently configured. For example, the external connection terminal 33 can be in the form of a flat piece with a plurality of gold fingers terminals, as shown in FIGS. 4 to 6. Alternatively, the external connection terminal 33 can be further connected to other types of quick disconnect connection terminals, such as that shown in FIG. 7, to be externally connected to a motherboard 50.

An electrical connection structure 60 is provided between the electrical connection section 41 of each fan unit 40 and each mating electrical connection section 31 on the fan electrical adapter board 30. At least a part of the electrical connection structures 60 are flexible electrical cords 61 respectively having a quick disconnect electrical connector 62 connected to a free end thereof. The flexible electrical cord 61 allows for an adaptation to any misalignment between the electrical connection section 41 and the mating electrical connection section 31. When the fan units 40 and the fan electrical adapter board 30 are assembled to the fan frame 20 and not all the electrical connection sections 41 are exactly aligned with or corresponding to the mating electrical connection sections 31, the flexible electrical cords 61 are flexible or adjustable to cover the misalignment in position or difference in type between the electrical connection sections 41 and the mating electrical connection section 31. Therefore, with the flexible electrical connection cords 61, the fan units 40 and the electrical connectors 31 on the fan electrical adapter board 30 are common in use with respect to each other. With this feature, the present invention largely overcomes the disadvantage in the conventional fan electrical connection structures that the fan electrical adapter boards are not common in use with respect to the fan units.

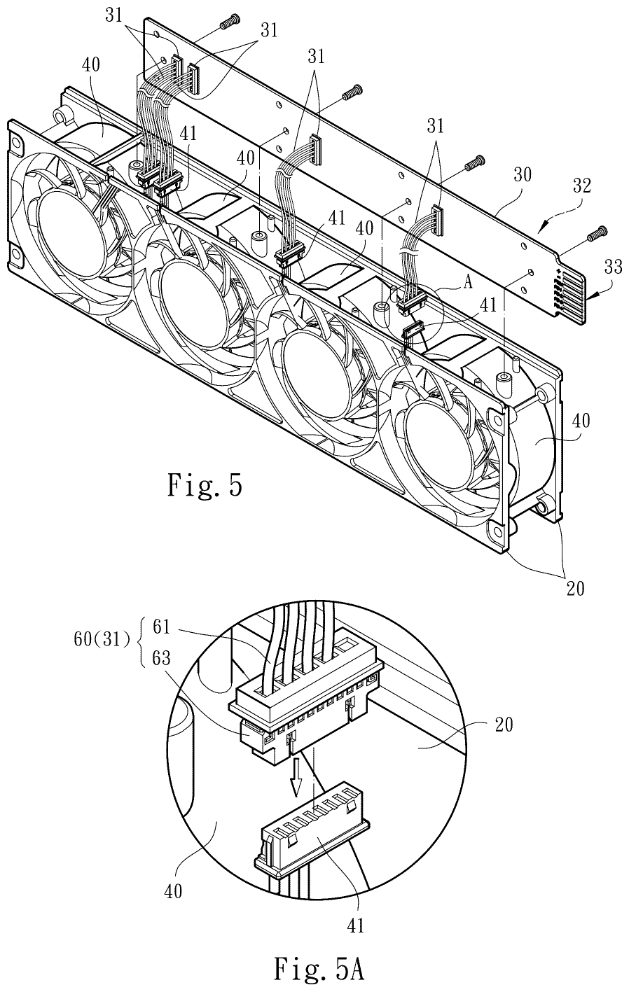

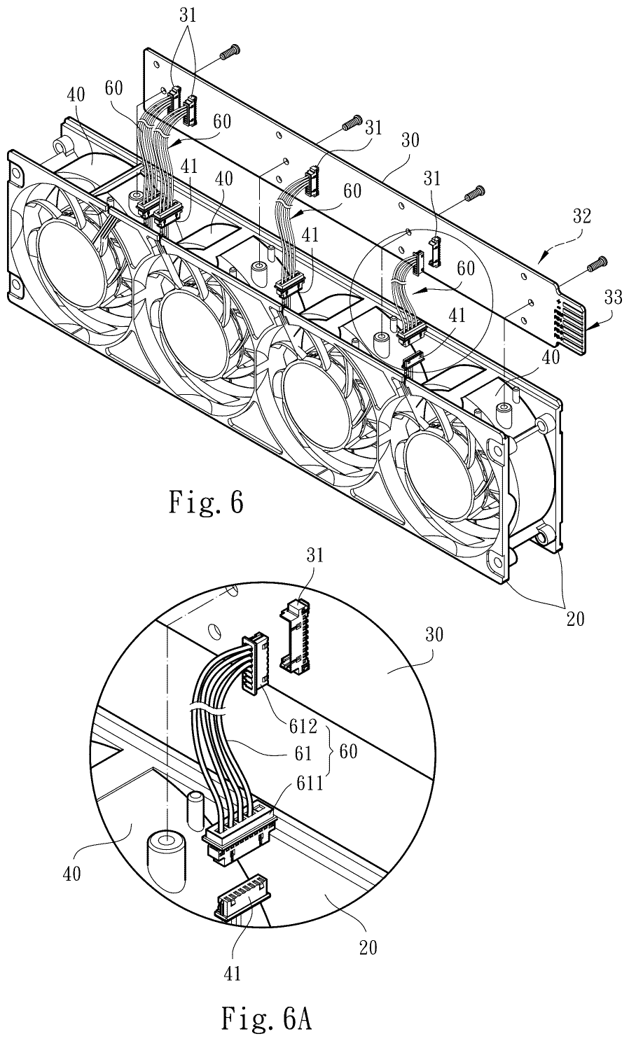

In practical implementation, the electrical connection structure 60 in a first embodiment may be configured as shown in FIG. 4. That is, the fan units 40 respectively have a quick disconnect electrical connector 62 connected thereto via a flexible electrical cord 61 to form the electrical connection section 41; and the mating electrical connection sections 31 on the fan electrical adapter board 30 are configured as quick disconnect electrical connectors that allow the quick disconnect electrical connector 62 to quickly connect thereto. Alternatively, the electrical connection structure 60 in a second embodiment may be configured as shown in FIG. 5, in which each of the mating electrical connection sections 31 on the fan electrical adapter board 30 has a flexible electrical cord 61 extended therefrom and a mating quick disconnect electrical connector 63 connected to a free end of the flexible electrical cord 61; and the electrical connection section 41 of each fan unit 40 is correspondingly configured as a quick disconnect electrical connector for connecting to the mating quick disconnect electrical connector 63. In a third embodiment, the electrical connection structure 60 may be configured as shown in FIG. 6, in which the electrical connection section 41 on each fan unit 40 is configured as a quick disconnect electrical connector and the mating electrical connection sections 31 on the fan electrical adapter board 30 are respectively configured as a mating quick disconnect electrical connector, and the flexible electrical cords 61 are respectively provided at two ends with a quick disconnect electrical connector 611, 612 for correspondingly connecting to the quick disconnect electrical connection section 41 and the mating quick disconnect electrical connection section 31, respectively. In the above three embodiments, at least three differently configured flexible electrical connection structures 60 are formed to adapt any misalignment between the electrical connection sections 41 or the mating electrical connection sections 31, so as to avoid the risk that the electrical connection sections 41 could not be connected to the mating electrical connection sections 31.

In the quick disconnect electrical connection structure according to the present invention, a part of the electrical connection structures 60 between the fan units 40 and the fan electrical adapter board 30 are flexible electrical cords 61 respectively having a quick disconnect electrical connector 62 assembled thereto. In the case the electrical connection sections 41 and the mating electrical connection sections 31 mounted on the fan frame 20 could not be correspondingly connected owing to any misalignment between them or any difference in the specifications and sizes between them, the flexible electrical cords 61 enables adaptation of the disalignment of the electrical connection sections 41 with respect to the mating electrical connection sections 31, allowing the electrical connection sections 41 to connect quickly to the mating electrical connection sections 31. The present invention with the above arrangements can fully overcome the disadvantage in the conventional electrical connection structure for fan module, and is therefore an improved fan module electrical connection structure practical for use.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A quick disconnect electrical connection structure for fan module, comprising a fan frame (20), a fan electrical adapter board (30), and a plurality of fan units (40);
the fan units (40) being assembled to an interior of the fan frame (20) and respectively including an electrical connection section (41) located at a position facing toward an electrical connection side (21) of the fan frame (20);
the fan electrical adapter board (30) being connected to the electrical connection side (21) of the fan frame (20) and having mating electrical connection sections (31) and circuit arrangements (32) provided thereon corresponding to the electrical connection sections (41) of the fan units (40); and the circuit arrangements (32) forming an external connection terminal (33) for electrically connecting an external device; and
the electrical connection section (41) of each fan unit (40) and each corresponding mating electrical connection section (31) on the fan electrical adapter board (30) having an electrical connection structure (60) provided between; at least a part of the electrical connection structures (60) being flexible electrical cords (61) respectively having a quick disconnect electrical connector (62) connected to a free end thereof; the flexible electrical cords (61) being adaptable to misalignment between the electrical connection section (41) and the mating electrical connection section (31); and the flexible electrical cords (61) providing flexible connection of the electrical connection sections (41) to the mating electrical connection sections (31) when the fan units (40) and the fan electrical adapter board (30) are assembled to the fan frame (20) and not all the electrical connection sections (41) are exactly aligned with the mating electrical connection sections (31).

2. The quick disconnect electrical connection structure for fan module as claimed in claim 1, wherein the flexible electrical cords (61) of the electrical connection structure (60) are respectively extended from one of the electrical connection sections (41) of the fan units (40) with the quick disconnect electrical connectors (62) connected to a free end thereof, and each of the mating electrical connection sections (31) on the fan electrical adapter board (30) being respectively configured as a mating quick disconnect electrical connector (63) for quickly connecting to the quick disconnect electrical connector (62).

3. The quick disconnect electrical connection structure for fan module as claimed in claim 1, wherein the flexible electrical cords (61) of the electrical connection structure (60) are respectively extended from one of the mating electrical connection sections (31) on the fan electrical adapter board (30) with a mating quick disconnect electrical connectors (63) connected to a free end thereof, and the electrical connection sections (41) of the fan units (40) being respectively configured as a quick disconnect electrical connector (62) for quickly connecting to the mating quick disconnect electrical connector (63).

4. The quick disconnect electrical connection structure for fan module as claimed in claim 1, wherein each of the electrical connection sections (41) of the fan units (40) and each of the mating electrical connectors (31) on the fan electrical adapter board (30) are configured as a quick disconnect electrical connector (62) and a mating quick disconnect electrical connector (63), respectively; and the flexible electrical cord (61) of each electrical connection structure (60) being provided at each of two opposite ends with a quick disconnect electrical connector (611, 612) for connecting to the quick disconnect electrical connector (62) and the mating quick disconnect electrical connector (63), respectively.

5. The quick disconnect electrical connection structure for fan module as claimed in claim 1, wherein the external connection terminal (33) is in the form of a flat piece with a plurality of gold fingers terminals.

6. The quick disconnect electrical connection structure for fan module as claimed in claim 2, wherein the external connection terminal (33) is in the form of a flat piece with a plurality of gold fingers terminals.

7. The quick disconnect electrical connection structure for fan module as claimed in claim 3, wherein the external connection terminal (33) is in the form of a flat piece with a plurality of gold fingers terminals.

8. The quick disconnect electrical connection structure for fan module as claimed in claim 4, wherein the external connection terminal (33) is in the form of a flat piece with a plurality of gold fingers terminals.

9. The quick disconnect electrical connection structure for fan module as claimed in claim 1, wherein the external connection terminal (33) is configured as a quick disconnect electrical connection terminal.

10. The quick disconnect electrical connection structure for fan module as claimed in claim 2, wherein the external connection terminal (33) is configured as a quick disconnect electrical connection terminal.

11. The quick disconnect electrical connection structure for fan module as claimed in claim 3, wherein the external connection terminal (33) is configured as a quick disconnect electrical connection terminal.

12. The quick disconnect electrical connection structure for fan module as claimed in claim 4, wherein the external connection terminal (33) is configured as a quick disconnect electrical connection terminal.
